(19) United States
(12) Patent Application Publication
(10) Pub. No.: US 2021/0407865 A1
(43) Pub. Date: Dec. 30, 2021

(54) Method of Manufacturing Semiconductor Device, Substrate Processing Apparatus and Non-transitory Computer-readable Recording Medium

(71) Applicant: Kokusai Electric Corporation, Tokyo (JP)

(72) Inventors: Kenji SHINOZAKI, Toyama (JP); Tetsuo YAMAMOTO, Toyama (JP); Yukitomo HIROCHI, Toyama (JP); Yoshihiko YANAGISAWA, Toyama (JP); Naoki HARA, Toyama (JP); Masaaki UENO, Toyama (JP); Hideto YAMAGUCHI, Toyama (JP); Hitoshi MURATA, Toyama (JP); Shuhei SAIDO, Toyama (JP); Kazuhiro KIMURA, Toyama (JP)

(21) Appl. No.: 17/473,664

(22) Filed: Sep. 13, 2021

Related U.S. Application Data
(63) Continuation of application No. PCT/JP2019/011062, filed on Mar. 18, 2019.

(51) Int. Cl. H01L 21/66; H01L 21/268; H01L 21/67; H05B 6/64; F27B 17/00; F27D 5/00

(52) U.S. Cl. CPC H01L 22/20; H01L 21/2686; H01L 21/67115; F27D 5/0037; H05B 6/645; F27B 17/0025; H01L 21/67248

(57) ABSTRACT

According to one aspect of the technique, there is provided a method of manufacturing a semiconductor device, including: (a) heating a heat insulating plate in a substrate retainer to a processing temperature by an electromagnetic wave, and measuring a temperature change of the heat insulating plate by a non-contact type thermometer until the processing temperature; (b) heating a test object provided with a chip that does not transmit a detection light of the thermometer and accommodated in the substrate retainer to the processing temperature, and measuring a temperature change of the chip by the thermometer until the processing temperature; (c) acquiring a correlation between the temperature change of the heat insulating plate and that of the chip based on measurement results; and (d) controlling a heater to heat the substrate based on the correlation and the temperature of the heat insulating plate measured by the thermometer.

### CROSS REFERENCE TO RELATED APPLICATIONS

This application is a continuation of International Application No. PCT/JP2019/011062, filed on Mar. 18, 2019, the entire contents of which are hereby incorporated by reference.

### TECHNICAL FIELD

The present disclosure relates to a method of manufacturing a semiconductor device, a substrate processing apparatus and a non-transitory computer-readable recording medium.

### BACKGROUND

As a part of manufacturing processes of a semiconductor device, an annealing process may be performed. For example, the annealing process is performed by heating a substrate in a process chamber by using a heater to change a composition and a crystal structure of a film formed on a surface of the substrate. Recently, the semiconductor device is miniaturized. Therefore, it is preferable that the annealing process is performed to the substrate such as a high density substrate on which a pattern is formed with a high aspect ratio.

However, in a conventional annealing process, a target film (that is, a film to be processed) may not be uniformly processed when the substrate cannot be uniformly heated.

### SUMMARY

Described herein is a technique capable of uniformly processing a target film.

According to one aspect of the technique of the present disclosure, there is provided a method of manufacturing a semiconductor device, including: (a) heating a heat insulating plate accommodated in a substrate retainer capable of accommodating a substrate to a processing temperature at which the substrate is processed by an electromagnetic wave supplied from a heater, and measuring a temperature change of the heat insulating plate by a non-contact type thermometer until a temperature of the heat insulating plate reaches the processing temperature; (b) heating a test object provided with a chip made of a material incapable of transmitting a detection light of the non-contact type thermometer and accommodated in the substrate retainer to the processing temperature by the heater, and measuring a temperature change of the chip by the non-contact type thermometer until a temperature of the chip reaches the processing temperature; (c) acquiring a correlation between the temperature change of the heat insulating plate and the temperature change of the chip based on measurement results of the temperature change of the heat insulating plate and measurement results of the temperature change of the chip; and (d) controlling the heater to heat the substrate based on the correlation and the temperature of the heat insulating plate measured by the non-contact type thermometer.

### BRIEF DESCRIPTION OF THE DRAWINGS

FIG. 1 is a diagram schematically illustrating a vertical cross-section of a single wafer type process furnace of a substrate processing apparatus preferably used in one or more embodiments described herein.

FIG. 2 is a block diagram schematically illustrating a configuration of a controller and related components of the substrate processing apparatus preferably used in the embodiments described herein.

FIG. 3 is a flow chart schematically illustrating a substrate processing according to the embodiments described herein.

FIG. 4A is a graph schematically illustrating a temperature transition by a temperature control according to the embodiments described herein, specifically, the temperature transition with respect to time by the temperature control when a temperature is elevated.

FIG. 4B is a graph schematically illustrating the temperature transition by the temperature control according to the embodiments described herein, specifically, the temperature transition with respect to time by the temperature control when the substrate processing is performed.

FIG. 4C is a diagram schematically illustrating a heating region of a wafer by the temperature control according to the embodiments described herein when the substrate processing is performed.

FIG. 5 is a diagram schematically illustrating a flow of creating a process conversion table preferably used in the embodiments described herein.

FIG. 6A is a diagram schematically illustrating a temperature measuring method when creating the process conversion table preferably used in the embodiments described herein, specifically, when measuring a temperature of a heat insulating plate.

FIG. 6B is a diagram schematically illustrating the temperature measuring method when creating the process conversion table preferably used in the embodiments described herein, specifically, when measuring a temperature of a quartz chip.

FIG. 7 is a graph schematically illustrating the temperature transition of the heat insulating plate with respect to time and the temperature transition of the quartz chip with respect to time measured by the temperature measuring method according to the embodiments described herein.

FIG. 8 is a temperature conversion graph schematically illustrating a correlation between the heat insulating plate and the quartz chip obtained from the graph of the heat insulating plate and the quartz chip shown in FIG. 7.

FIG. 9 is a diagram schematically illustrating a first modified example of the embodiments described herein.

FIG. 10 is a diagram schematically illustrating a second modified example of the embodiments described herein.

### DETAILED DESCRIPTION

### Embodiments

Hereinafter, one or more embodiments (also simply referred to as “embodiments”) according to the technique of the present disclosure will be described with reference to the drawings.

### (1) Configuration of Substrate Processing Apparatus

According to the present embodiments, for example, a substrate processing apparatus 100 is configured as a single wafer type heat treatment apparatus capable of performing various heat treatment processes on a wafer.

### Process Chamber

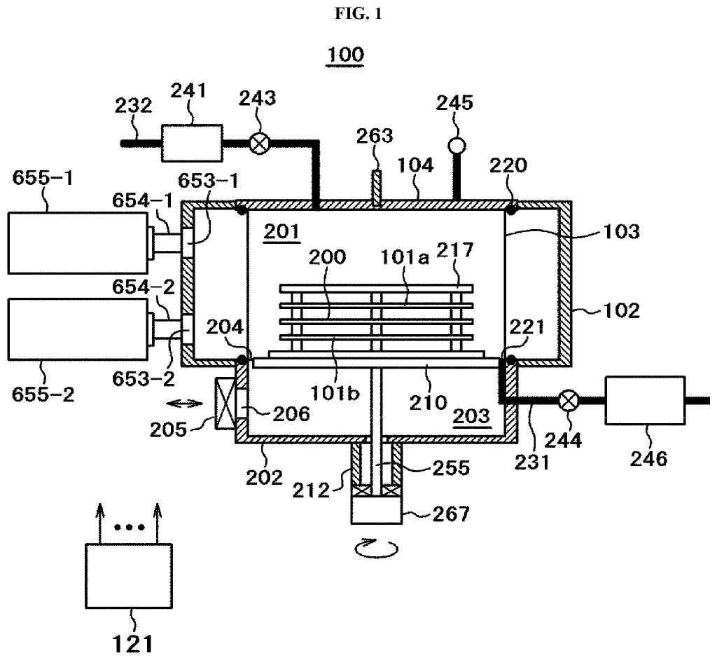

As shown in FIG. 1, the substrate processing apparatus 100 according to the present embodiments may include: a case 102 serving as a cavity made of a material such as a metal capable of reflecting an electromagnetic wave; and a reaction tube 103 of a cylindrical shape accommodated in the case 102 and whose upper and lower ends in a vertical direction are open. The reaction tube 103 is made of a material such as quartz capable of transmitting the electromagnetic wave. A cap flange (which is a closing plate) 104 made of a metal material is in contact with the upper end of the reaction tube 103 to close (seal) the upper end of the reaction tube 103 via an O-ring 220 serving as a seal. A process vessel in which a substrate such as a silicon wafer is processed is constituted mainly by the case 102, the reaction tube 103 and the cap flange 104, and in particular, a process chamber 201 is constituted by an inner space of the reaction tube 103.

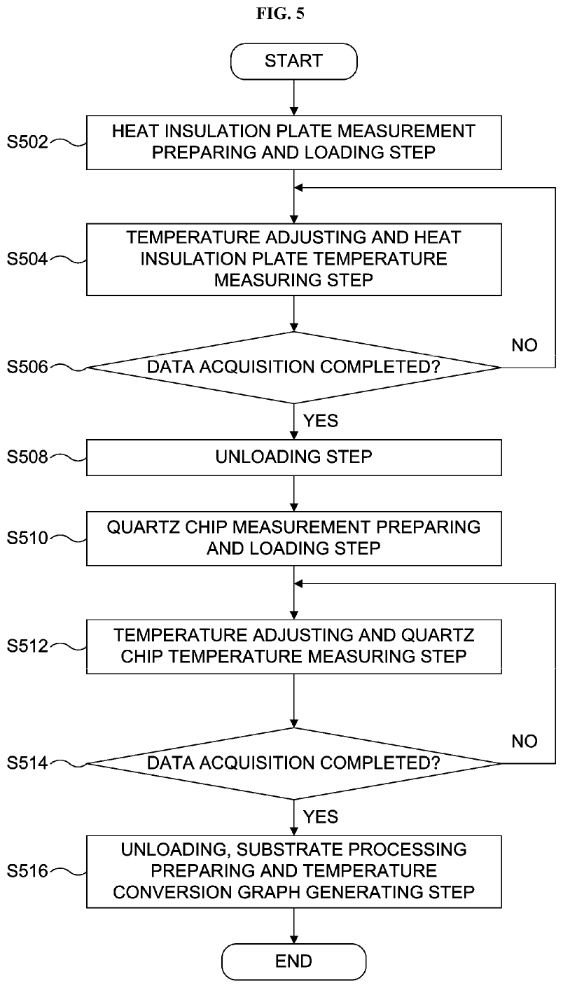

A placement table (which is a mounting table) 210 is provided below the reaction tube 103. A boat 217 serving as a substrate retainer configured to hold (or support) a wafer 200 to be processed (or a plurality of wafers including the wafer 200) is placed on an upper surface of the placement table 210. Hereinafter, the plurality of wafers including the wafer 200 may also be simply referred to as wafers 200. The wafer 200 to be processed and heat insulating plates 101a and 101b are accommodated in the boat 217 such that the wafer 200 is interposed between the heat insulating plates 101a and 101b with a predetermined interval. For example, the heat insulating plates 101a and 101b may be configured as a quartz plate such as a dummy wafer or a silicon plate (Si plate). The heat insulating plates 101a and 101b are provided to maintain (retain) a temperature of the wafer 200. On a side wall of the placement table 210, a protrusion (not shown) protruding in a radial direction of the placement table 210 is provided on a bottom of the placement table 210. When the protrusion approaches or comes into contact with a partition plate 204 provided between the process chamber 201 and a transfer space 203 described later, it is possible to prevent (or suppress) an inner atmosphere of the process chamber 201 from entering the transfer space 203 and an inner atmosphere of the transfer space 203 from entering the process chamber 201. According to the present embodiments, a plurality of heat insulating plates serving as the heat insulating plate 101a and a plurality of heat insulating plates serving as the heat insulating plate 101b may be installed depending on a substrate processing temperature. By providing the plurality of heat insulating plates as the heat insulating plate 101a or the plurality of heat insulating plates as the heat insulating plate 101b, it is possible to suppress the heat dissipation in a region where the wafer 200 is placed, and it is also possible to improve a temperature uniformity on a surface of the wafer 200 or a temperature uniformity between the wafers 200. Further, as shown in FIG. 6A, which will be described later, a hole 217b serving as a measurement window of a temperature sensor 263 is provided at an end plate (ceiling plate) 217a of the boat 217, and the heat insulating plate 101a is held (supported) in the boat 217 such that the temperature sensor 263 can measure a surface temperature of the heat insulating plate 101a through the hole 217b.

The case 102 serving as an upper vessel is a flat and sealed vessel with a circular horizontal cross-section. A transfer vessel 202 serving as a lower vessel is made of a metal material such as aluminum (Al) and stainless steel (SUS), or is made of a material such as quartz. The transfer space 203 through which the wafer 200 serving as a substrate such as a silicon substrate is transferred is provided below the process vessel. A space above the partition plate 204 surrounded by the case 102 or surrounded by the reaction tube 103 may be referred to as the process chamber 201 or a reaction region 201 and a space below the partition plate 204 surrounded by the transfer vessel 202 may be referred to as the transfer space 203 or a transfer region 203.

A substrate loading/unloading port 206 is provided adjacent to a gate valve 205 at a side surface of the transfer vessel 202. The wafer 200 is transferred between the transfer space 203 and a substrate transfer chamber (not shown) through the substrate loading/unloading port 206.

Electromagnetic wave introduction ports 653-1 and 653-2 are provided at a side surface of the case 102. One end of a waveguide 654-1 and one end of a waveguide 654-2 through which the electromagnetic wave is supplied into the process chamber 201 are connected to the electromagnetic wave introduction ports 653-1 and 653-2, respectively. The other end of the waveguide 654-1 and the other end of the waveguide 654-2 are connected to microwave oscillators (hereinafter, also referred to as electromagnetic wave sources) 655-1 and 655-2, respectively, serving as heating sources configured to supply the electromagnetic wave into the process chamber 201 to heat the process chamber 201. In the present specification, unless they need to be distinguished separately, the electromagnetic wave introduction ports 653-1 and 653-2 may be collectively or individually referred to as an electromagnetic wave introduction port 653, the waveguides 654-1 and 654-2 may be collectively or individually referred to as a waveguide 654, and the microwave oscillators 655-1 and 655-2 may be collectively or individually referred to as a microwave oscillator 655.

The placement table 210 is supported by a shaft 255 serving as a rotating shaft. The shaft 255 penetrates a bottom of the transfer vessel 202, and is connected to a driver (which is a driving structure) 267 at an outside of the transfer vessel 202. The driver 267 is configured to rotate, elevate or lower the shaft 255. The wafer 200 accommodated in the boat 217 may be rotated, elevated or lowered by rotating, elevating or lowering the shaft 255 and the placement table 210 by operating the driver 267. A bellows 212 covers a lower end of the shaft 255 and its periphery to maintain an inside of the process chamber 201 and an inside of the transfer region 203 airtight.

The placement table 210 is lowered until the upper surface of the placement table 210 reaches a position of the substrate loading/unloading port 206 (hereinafter, also referred to as “wafer transfer position”) when the wafer 200 is transferred, and the placement table 210 is elevated until the wafer 200 reaches a processing position in the process chamber 201 (hereinafter, also referred to as a “wafer processing position”) when the wafer 200 is processed.

### Exhauster

An exhauster (which is an exhaust structure) configured to exhaust the inner atmosphere of the process chamber 201 is provided below the process chamber 201 on an outer circumference of the placement table 210. As shown in FIG. 1, an exhaust port 221 is provided in the exhauster. An exhaust pipe 231 is connected to the exhaust port 221. A pressure regulator (also referred to as a “pressure adjusting structure”) 244 such as an APC (Automatic Pressure regulator) valve and a vacuum pump 246 are sequentially connected to the exhaust pipe 231 in series. For example, the APC valve capable of adjusting an opening degree thereof in accordance with an inner pressure of the process chamber 201 may be used as the pressure regulator 244. In the present specification, the pressure regulator 244 may also be referred to as the APC valve 244. However, in the embodiments, the pressure regulator 244 is not limited to the APC valve. The pressure regulator 244 may be embodied by a combination of a conventional opening/closing valve and a pressure regulating valve so long as it is possible to receive information on the inner pressure of the process chamber 201 (that is, a feedback signal from a pressure sensor 245 which will be described later) and to adjust an exhaust amount based on the received information.

The exhauster (also referred to as an “exhaust system” or an “exhaust line”) is constituted mainly by the exhaust port 221, the exhaust pipe 231 and the pressure regulator 244. It is also possible to configure the exhaust line to surround the process chamber 201 such that the gas may be exhausted from the entirety of a circumference of the wafer 200 through the exhaust line surrounding the process chamber 201. The exhauster may further include the vacuum pump 246.

### Gas Supplier

The cap flange 104 is provided with a gas supply pipe 232 through which a process gas such as an inert gas, a source gas and a reactive gas used for performing various substrate processing is supplied into the process chamber 201. A mass flow controller (MFC) 241 serving as a flow rate controller (flow rate control structure) and a valve 243 serving as an opening/closing valve are sequentially installed at the gas supply pipe 232 in order from an upstream side to a downstream side of the gas supply pipe 232. For example, a nitrogen (N₂) gas supply source (not shown) serving as a source of the inert gas is connected to the upstream side of the gas supply pipe 232, and the N₂ gas serving as the inert gas is supplied into the process chamber 201 via the MFC 241 and the valve 243. When two or more kinds of gases are used for the substrate processing, it is possible to supply the gases into the process chamber 201 by connecting one or more gas supply pipes to the gas supply pipe 232 at a downstream side of the valve 243 provided at the gas supply pipe 232. An MFC serving as a flow rate controller and a valve serving as an opening/closing valve may be sequentially installed at each of the one or more gas supply pipes in order from an upstream side to a downstream side of each of the one or more gas supply pipes.

A gas supplier (which is a gas supply system or a gas supply structure) is constituted mainly by the gas supply pipe 232, the MFC 241 and the valve 243. When the inert gas is supplied through the gas supply pipe 232, the gas supplier may also be referred to as an inert gas supplier (which is an inert gas supply system or an inert gas supply structure). For example, a rare gas such as argon (Ar) gas, helium (He) gas, neon (Ne) gas and xenon (Xe) gas may be used as the inert gas instead of the N₂ gas.

### Temperature Sensor

The temperature sensor 263 serving as a non-contact type temperature detector (or a non-contact type thermometer) is provided at the cap flange 104. By adjusting an output of the microwave oscillator 655 described later based on temperature information detected by the temperature sensor 263, the wafer 200 serving as the substrate is heated such that a desired temperature distribution of the wafer 200 can be obtained. For example, the temperature sensor 263 is constituted by a radiation thermometer such as an IR (Infrared Radiation) sensor. A method of measuring the temperature of the substrate (that is, the wafer 200) is not limited to using the radiation thermometer described above. For example, the temperature of the wafer 200 may be measured using a thermocouple, or the temperature of the wafer 200 may be measured using both of the thermocouple and the radiation thermometer. However, when the temperature of the wafer 200 is measured using the thermocouple, in order to improve a temperature measurement accuracy of the thermocouple, it is preferable that the thermocouple is provided in the vicinity of the wafer 200 to be processed to measure the temperature the wafer 200. When the thermocouple is provided in the vicinity of the wafer 200, the thermocouple itself is heated by a microwave supplied from the microwave oscillator 655 described later. Therefore, it is preferable to use the radiation thermometer as the temperature sensor 263. While the present embodiments are described by way of an example in which the temperature sensor 263 is provided at the cap flange 104, the present embodiments are not limited thereto. For example, the temperature sensor 263 may be provided at the placement table 210. With such a configuration, it is possible to use a reaction tube whose upper end is closed, and it is also possible to reduce a possibility of a leakage of, for example, the microwave and the process gas supplied to the process chamber 201. For example, according to the present embodiments, the temperature sensor 263 is directly disposed at the cap flange 104 or the placement table 210. However, instead of providing the temperature sensor 263 directly at the cap flange 104 or the placement table 210, the temperature sensor 263 may measure the temperature of the wafer 200 indirectly by measuring the radiation reflected by a component such as a mirror and emitted through a measurement window provided in the cap flange 104 or the placement table 210. When the temperature sensor 263 measures the temperature of the wafer 200 indirectly as described above, it is possible to relax a restriction on an installation location where the temperature sensor 263 is installed.

### Microwave Oscillator

As described above, the electromagnetic wave introduction ports 653-1 and 653-2 are provided at a side wall of the case 102. One end of the waveguide 654-1 and one end of the waveguide 654-2 through which the electromagnetic wave is supplied into the process chamber 201 are connected to the electromagnetic wave introduction ports 653-1 and 653-2, respectively. The other end of the waveguide 654-1 and the other end of the waveguide 654-2 are connected to the microwave oscillators (hereinafter, also referred to as the electromagnetic wave sources) 655-1 and 655-2, respectively, serving as the heating sources configured to supply the electromagnetic wave into the process chamber 201 to heat the process chamber 201. The microwave oscillators 655-1 and 655-2 are configured to supply the electromagnetic wave such as the microwave to the waveguides 654-1 and 654-2, respectively. For example, a magnetron or a klystron may be used as the microwave oscillators 655-1 and 655-2. Preferably, a frequency of the electromagnetic wave generated by the microwave oscillator 655 is controlled such that the frequency is within a range from 13.56 MHz to 24.125 GHz. More preferably, the frequency is controlled to a frequency of 2.45 GHz or 5.8 GHz. While the two microwave oscillators 655-1 and 655-2 are provided on the same side surface of the case 102 according to the present embodiments, the present embodiments are not limited thereto. For example, the microwave oscillator 655 including at least one microwave oscillator may be provided according to the present embodiments. In addition, the microwave oscillator 655-1 may be provided on the side surface of the case 102 and the microwave oscillator 655-2 may be provided on another side surface of the case 102 which, for example, faces the above-mentioned side surface of the case 102 at which the microwave oscillator 655-1 is provided. With such a configuration, it is possible to suppress the wafer 200 from being locally heated by suppressing the wafer 200 and its region from locally absorbing the microwave described later, so that it is possible to improve the temperature uniformity on the surface of the wafer 200. An electromagnetic wave supplier (which is an electromagnetic wave supply structure or an electromagnetic wave supply apparatus) serving as a heater is constituted mainly by the microwave oscillators 655-1 and 655-2, the waveguides 654-1 and 654-2 and the electromagnetic wave introduction ports 653-1 and 653-2. The electromagnetic wave supplier may also be referred to as a microwave supplier (which is a microwave supply structure or a microwave supply apparatus).

A controller 121 described later is connected to each of the microwave oscillators 655-1 and 655-2. The temperature sensor 263 configured to measure the temperature of the heat insulating plate 101a (or the heat insulating plate 101b) or the temperature of the wafer 200 accommodated in the process chamber 201 is connected to the controller 121. The temperature sensor 263 may be configured to measure the temperature of the heat insulating plate 101a (or the heat insulating plate 101b) or the temperature of the wafer 200 and to transmit the measured temperature to the controller 121. The controller 121 is configured to control the heating of the wafer 200 by controlling the outputs of the microwave oscillators 655-1 and 655-2. According to the present embodiments, for example, the microwave oscillators 655-1 and 655-2 are controlled by the same control signal transmitted from the controller 121. However, the present embodiments are not limited thereto. For example, the microwave oscillator 655-1 and the microwave oscillator 655-2 may be individually controlled by individual control signals transmitted from the controller 121 to the microwave oscillator 655-1 and the microwave oscillator 655-2, respectively.

### Controller

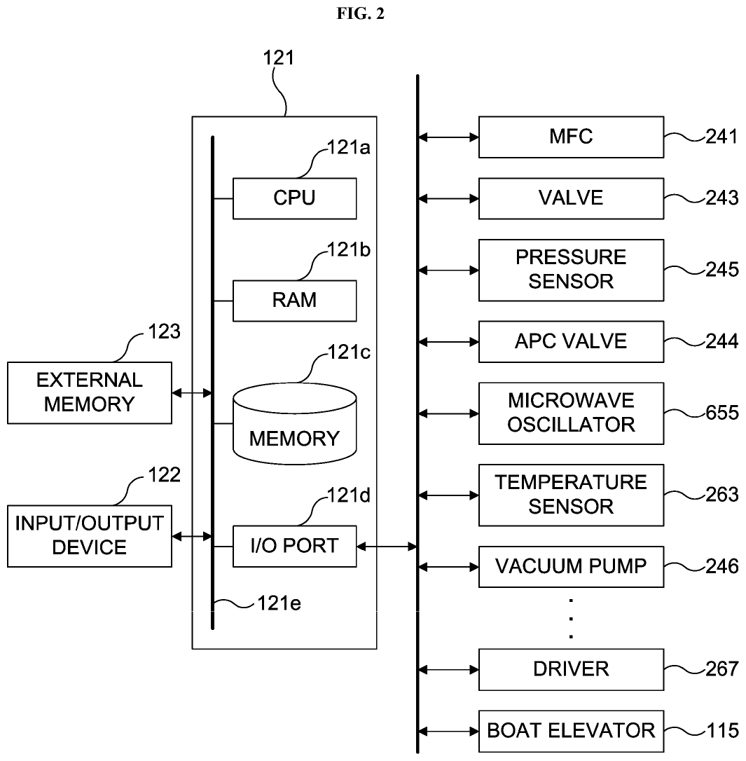

As shown in FIG. 2, the controller 121 serving as a control structure (or a control apparatus) may be constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 such as a touch panel is connected to the controller 121.

For example, the memory 121c is configured by a component such as a flash memory and an HDD (Hard Disk Drive). For example, a control program configured to control the operation of the substrate processing apparatus 100, an etching recipe containing information on the sequences and conditions of an etching process or a process recipe containing information on the sequences and conditions of a film-forming process may be readably stored in the memory 121c. The etching recipe or the process recipe is obtained by combining steps of the substrate processing described later such that the controller 121 can execute the steps to acquire a predetermined result, and functions as a program. Hereinafter, the etching recipe, the process recipe and the control program may be collectively or individually referred to as a “program”. The etching recipe or the process recipe may be simply referred to as a “recipe”. In the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the mass flow controller (MFC) 241, the valve 243, the pressure sensor 245, the APC valve 244, the vacuum pump 246, the temperature sensor 263, the driver 267 and the microwave oscillator 655.

The CPU 121a is configured to read the control program from the memory 121c and execute the read control program. Furthermore, the CPU 121a is configured to read the recipe from the memory 121c according to an operation command inputted from the input/output device 122. According to the contents of the read recipe, the CPU 121a may be configured to control various operations such as a flow rate adjusting operation for various gases by the MFC 241, an opening and closing operation of the valve 243, an opening and closing operation of the APC valve 244, a pressure adjusting operation by the APC valve 244 based on the pressure sensor 245, a start and stop of the vacuum pump 246, an output adjusting operation by the microwave oscillator 655 based on the temperature sensor 263, an operation of adjusting rotation and rotation speed of the placement table 210 (or an operation of adjusting rotation and rotation speed of the boat 217) by the driver 267 and an elevating and lowering operation of the placement table 210 (or an elevating and lowering operation of the boat 217) by the driver 267.

The controller 121 may be embodied by installing the above-described program stored in an external memory 123 into a computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication means such as the Internet and a dedicated line may be used for providing the program to the computer.

### (2) Substrate Processing

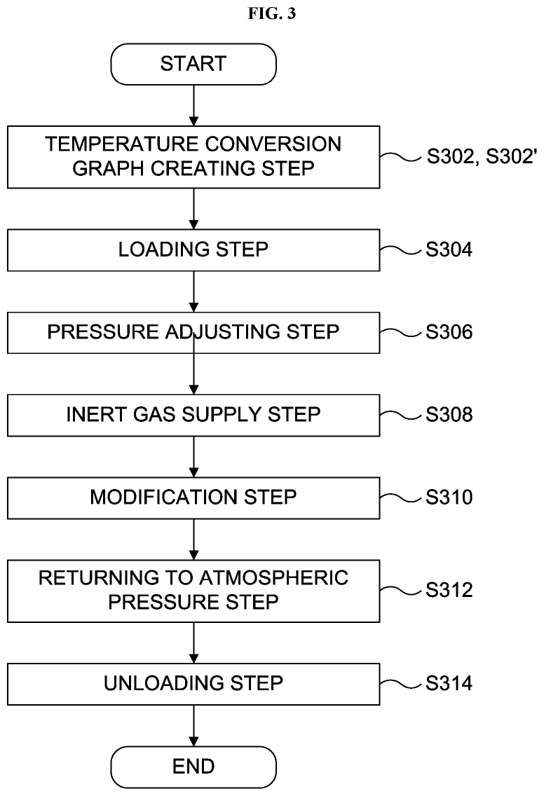

Hereinafter, an exemplary sequence of a method (that is, the substrate processing) of modifying (crystallizing) a film formed on the wafer 200 serving as the substrate, which is a part of manufacturing processes of a semiconductor device, will be described with reference to a flow chart shown in FIG. 3. For example, the film such as an amorphous silicon film serving as a silicon-containing film is processed according to the substrate processing. The exemplary sequence of the substrate processing is performed by using the process furnace of the substrate processing apparatus 100 described above. Hereinafter, the components constituting the substrate processing apparatus 100 are controlled by the controller 121.

In the present specification, the term “wafer” may refer to “a wafer (or a product wafer) itself” or may refer to “a wafer and a stacked structure (aggregated structure) of a predetermined layer (or layers) or a film (or films) formed on a surface of a wafer”. In the present specification, the term “a surface of a wafer” may refer to “a surface of a wafer itself” or may refer to “a surface of a predetermined layer or a film formed on a wafer”. Thus, in the present specification, “forming a predetermined layer (or film) on a wafer” may refer to “forming a predetermined layer (or film) on a surface of a wafer itself” or may refer to “forming a predetermined layer (or film) on a surface of another layer or another film formed on a wafer”. In the present specification, the terms “substrate” and “wafer” may be used as substantially the same meaning. That is, the term “substrate” may be substituted by “wafer” and vice versa.

### Temperature Conversion Graph Creating Step (S302)

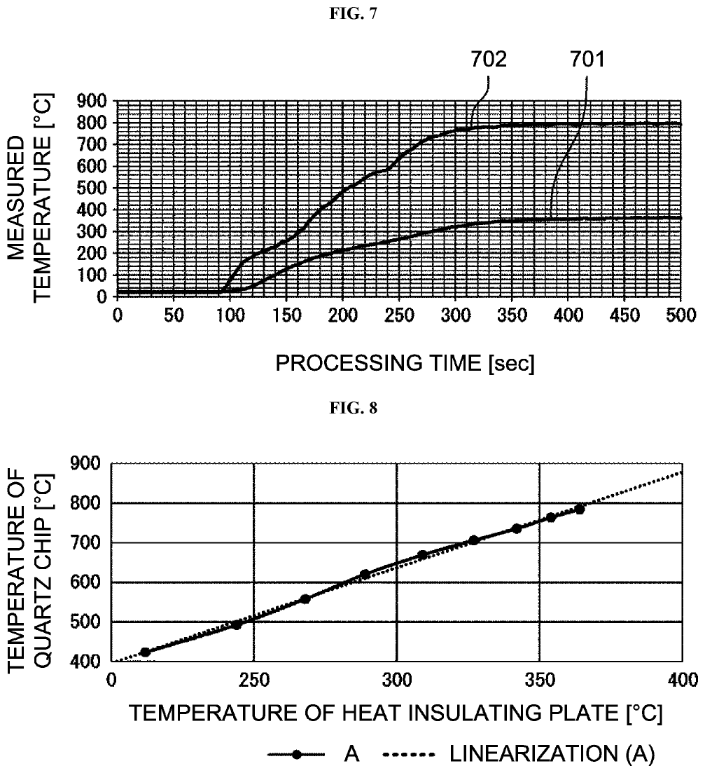

As a preliminary step before performing a predetermined substrate processing, by using the heat insulating plate 101a, the temperature sensor 263, a target substrate (target wafer) 603, a perforated heat insulating plate 602 and a chip (hereinafter, also referred to as a quartz chip) 604 made of a material (for example, quartz) that does not transmit a detection light of the temperature sensor 263, a data acquisition process of creating a temperature conversion graph as shown in FIG. 8 representing a correlation between the heat insulating plate 101a and the quartz chip 604, which will be described later, is performed (step S302). It is to be noted that “target substrate” of the above may also be referred to as “test object” or “target wafer”.

### Loading Step S304

As shown in FIG. 1, after a predetermined number of wafers including the wafer 200 are transferred to the boat 217, a boat elevator 115 elevates the boat 217 such that the boat 217 is loaded into the process chamber 201 in the reaction tube 103 as shown in FIG. 3 (boat loading step) (step S304).

### Pressure Adjusting Step S306

After the boat 217 is loaded into the process chamber 201, the inner atmosphere of the process chamber 201 is controlled (adjusted) such that the inner pressure of the process chamber 201 reaches and is maintained to a predetermined pressure (for example, a pressure ranging from 10 Pa to 100 Pa). Specifically, the opening degree of the pressure regulator 244 is feedback-controlled based on the pressure information detected by the pressure sensor 245 to adjust the inner pressure of the process chamber 201 to the predetermined pressure while vacuum-exhausting the process chamber 201 by the vacuum pump 246 (step S306).

### Inert Gas Supply Step S308

The driver 267 rotates the wafer 200 via the boat 217. While the driver 267 rotates the wafer 200, the inert gas such as the N₂ gas is supplied into the process chamber 201 through the gas supply pipe 232 (step S308). In the inert gas supply step S308, for example, the inner pressure of the process chamber 201 is adjusted to a predetermined pressure ranging from 1 Pa to 200,000 Pa, and preferably from 1 Pa to 300 Pa.

### Modification Step S310

The microwave oscillators 655-1 and 655-2 elevate the temperature of the wafer 200 to a temperature ranging from 100° C. to 900° C. (for example, 400° C.). The temperature of the wafer 200 may be estimated and controlled based on data of the temperature conversion graph created and stored in the temperature conversion graph creating step S302. The data of the temperature conversion graph may be obtained by measuring the surface temperature of the heat insulating plate 101a by the temperature sensor 263. The microwave oscillators 655-1 and 655-2 supply the microwave into the process chamber 201 through the electromagnetic wave introduction ports 653-1 and 653-2 and the waveguides 654-1 and 654-2. Since the microwave supplied into the process chamber 201 enter the wafer 200 and is efficiently absorbed, it is possible to elevate the temperature of the wafer 200 extremely effectively.

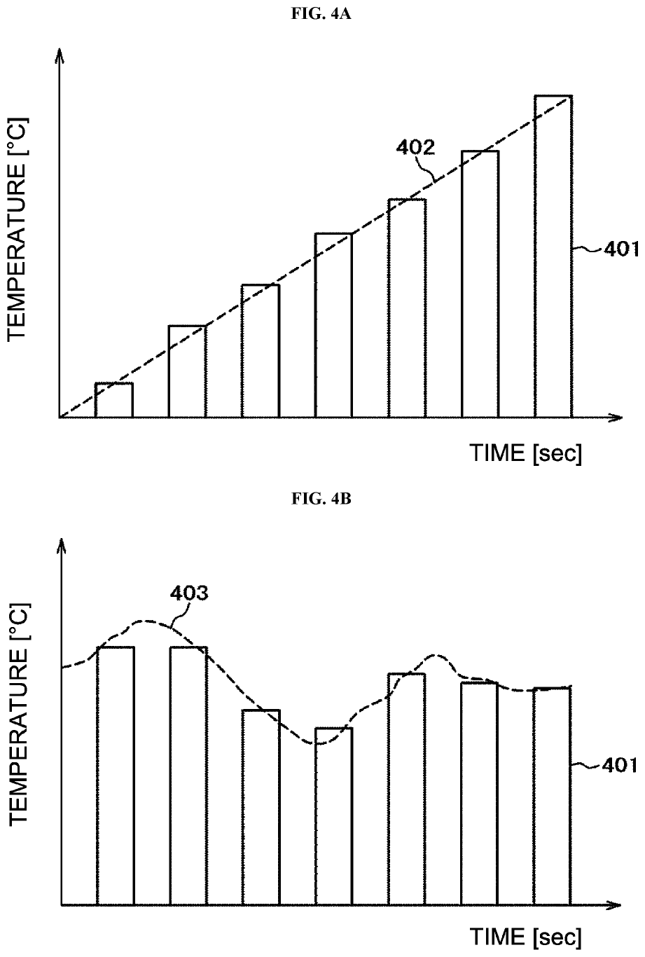

In the modification step S310, when elevating the temperature of the wafer 200, preferably, the microwave oscillators 655-1 and 655-2 may be controlled so as to increase the outputs of the microwave oscillators 655-1 and 655-2 while intermittently supplying the microwave. That is, as shown in FIG. 4A, it is preferable to combine a pulse control 401 of supplying the microwave intermittently from the microwave oscillators 655-1 and 655-2 and a power limit control 402 of maintaining a linearity of the outputs of the microwave oscillators 655-1 and 655-2. Standing waves may be generated in the process chamber 201 so that a region (also referred to as a “microwave concentrated region” or a “hot spot”) 404 which is intensively heated may be formed on the surface of the wafer 200 as shown in FIG. 4C. However, according to the present embodiments, the microwave is supplied while being pulse-controlled (that is, while performing the pulse control 401) when elevating the temperature of the wafer 200. Thus, a time duration (OFF time) during which no microwave is supplied may be provided according to the present embodiments. By providing the OFF time during which no microwave is supplied, the heat generated in the microwave concentrated region 404 is transferred to the entire surface of the wafer 200. Therefore, the temperature of the wafer 200 becomes uniform throughout the entire surface of the wafer 200. By providing a time (that is, the OFF time) during which the heat is transferred to the entire surface of the wafer 200 as described above, it is possible to prevent (or suppress) the microwave concentrated region 404 from being heated intensively. Therefore, by supplying the microwave while performing the pulse control 401 as described above, it is possible to suppress a temperature difference between the microwave concentrated region 404 and the other regions on the surface of the wafer 200, which is caused by the microwave concentrated region 404 being heated intensively and continuously. It is also possible to suppress a deformation of the wafer 200 such as a cracking, a warping and a distortion caused by the temperature difference generated on the surface of the wafer 200. In addition, by supplying the microwave while being power-limit-controlled (that is, while performing the power limit control 402) when elevating the temperature of the wafer 200, it is possible to efficiently elevate the temperature of the wafer 200, and it is also possible to heat the wafer 200 to a desired substrate processing temperature in a short time.

Subsequently, when the temperature of the wafer 200 is completely elevated, the microwave oscillators 655-1 and 655-2 are controlled such that the temperature measured by the temperature sensor 263 serving as the substrate processing temperature is maintained within a constant range. Specifically, the temperature measured by the temperature sensor 263 is converted based on the temperature conversion graph shown in FIG. 8 created in the temperature conversion graph creating step (S302), and the microwave oscillators 655-1 and 655-2 are controlled (a temperature control is performed). When performing the temperature control, as shown in FIG. 4B, the temperature measured by the temperature sensor 263 is fed back to the controller 121, and a feedback control 403 of controlling the microwave oscillators 655-1 and 655-2 is performed based on the fed back data. In parallel with the feedback control 403, by performing the pulse control 401 shown in FIG. 4B similar to the pulse control 401 performed when elevating the temperature of the wafer 200, the substrate processing temperature may be controlled to be within a certain range. By controlling the microwave oscillators 655-1 and 655-2 as described above, it is possible to maintain the temperature of the wafer 200 at the substrate processing temperature within a predetermined range. The pulse control 401 shown in FIG. 4B is performed when maintaining the temperature for the same reasons as those for the pulse control 401 shown in FIG. 4A performed when elevating the temperature of the wafer 200.

In the modification step S310, it is preferable to control an interval between a time (ON time) during which the microwave is supplied by the microwave oscillators 655-1 and 655-2 and a time (OFF time) during which the microwave is not supplied by the microwave oscillators 655-1 and 655-2 (that is, a pulse width) such that the interval is equal to, for example, 1×10-4 sec. With such a configuration, it is possible to perform the temperature control accurately both when the temperature of the wafer 200 is elevated and when the wafer 200 is processed. Further, the pulse width may be controlled to vary between when the temperature of the wafer 200 is elevated and when the wafer 200 is processed. When the temperature of the wafer 200 is elevated, the temperature difference between the microwave concentrated region 404 and the other regions on the surface of the wafer 200 tends to be large (that is, the other regions are hardly heated). Therefore, according to the present embodiments, by decreasing the pulse width when the temperature of the wafer 200 is elevated, it is possible to improve the temperature uniformity on the surface of the wafer 200. When the wafer 200 is processed, the temperature difference between the microwave concentrated region 404 and the other regions on the surface of the wafer 200 is unlikely to be large (that is, the other regions are heated to some extent). Therefore, by increasing the pulse width when the wafer 200 is processed, it is possible to sufficiently irradiate the surface of the wafer 200 with the microwave, and it is also possible to sufficiently process the wafer 200. In addition, a time duration of the ON time and a time duration of the OFF time of the pulse width may be controlled to be different from each other. By heating the wafer 200 as described above, the film such as the amorphous silicon film formed on the surface of the wafer 200 is modified (crystallized) into a polysilicon film. That is, it is possible to uniformly modify the wafer 200.

After a predetermined processing time has elapsed, the rotation of the boat 217, the supply of the gas, the supply of the microwave and the exhaust via the exhaust pipe 231 are stopped (step S310).

### Returning to Atmospheric Pressure Step S312

After the modification Step S310 is completed, the inert gas such as the N₂ gas is supplied to return the inner pressure of the process chamber 201 to the atmospheric pressure (step S312).

### Unloading Step S314

After returning the inner pressure of the process chamber 201 to the atmospheric pressure, the driver 267 lowers the placement table 210 to open a furnace opening, and transfers (unloads) the boat 217 to the transfer space 203 (boat unloading step). After the boat 217 is unloaded, the wafer 200 accommodated in the boat 217 is transferred (discharged) out of the transfer space 203 to the substrate transfer chamber (not shown) provided outside the transfer space 203 (step S314). By performing the steps described above, the modification process is performed to the wafer 200.

### (3) Temperature Conversion Graph Creating Step

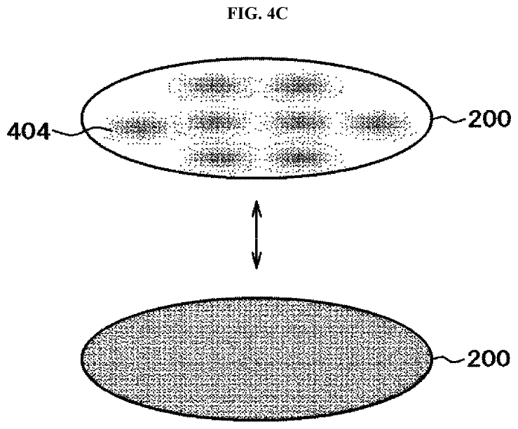

Subsequently, a detailed process flow of the temperature conversion graph creating step S302 will be described with reference to FIGS. 5 through 8. The present embodiments will be described by an example in which the temperature conversion graph is created in the temperature conversion graph creating step S302 for convenience of explanation. However, the temperature conversion graph may not be created. That is, data capable of creating the temperature conversion graph may be obtained instead of creating the temperature conversion graph itself.

### Heat Insulating Plate Measurement Preparing and Loading Step S502

As shown in FIG. 6A, as described above, the hole 217b serving as the measurement window of the temperature sensor 263 is provided at the end plate (ceiling plate) 217a of the boat 217, and the heat insulating plate 101a is held (supported) in the boat 217 such that the temperature sensor 263 can measure the surface temperature of the heat insulating plate 101a through the hole 217b. In addition, similarly, a dummy wafer (which is a dummy substrate) 601 and the heat insulating plate 101b are held (supported) in the boat 217. For example, the dummy wafer 601 is made of a material different from that of the wafer 200 such as the product wafer, and thermal characteristics of the dummy wafer 601 are similar to thermal characteristics of the wafer 200. When the heat insulating plates 101a and 101b and the dummy wafer 601 are held at predetermined positions of the boat 217, the boat 217 is loaded into the process chamber 201 (step S502). While the step S502 is described by way of an example in which the dummy wafer 601 is held in the boat 217, the product wafer may be held in the boat 217 instead of the dummy wafer 601.

### Temperature Adjusting and Heat Insulating Plate Temperature Measuring Step S504

When the boat 217 is loaded into a predetermined substrate processing position, the microwave is supplied from the microwave oscillator 655 by controlling the microwave oscillator 655 using a control method such as the pulse control 401 and the power limit control 402 described above so as to perform a temperature adjusting operation such as elevating the temperature of the wafer 200 to the substrate processing temperature and maintaining the temperature of the wafer 200. While the temperature adjusting operation is being performed, the measurement of the surface temperature of the heat insulating plate 101a is started at a predetermined start timing and performed for a predetermined time by the temperature sensor 263 (step S504).

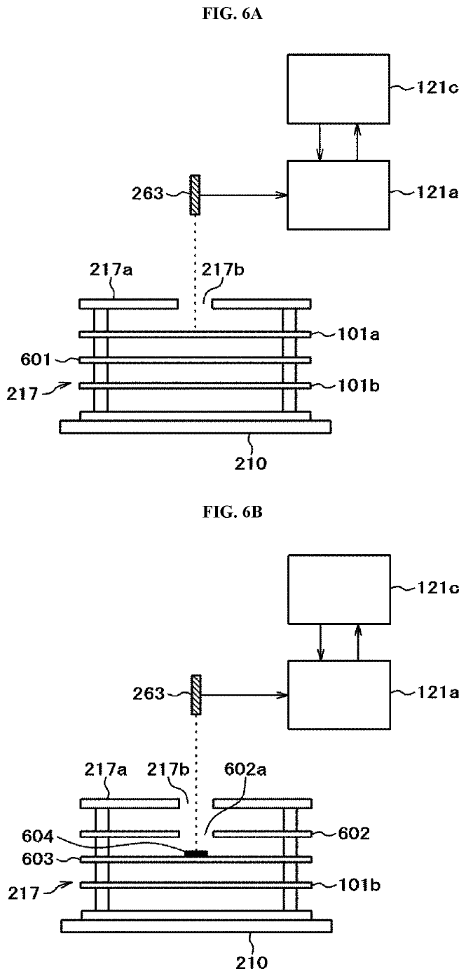

The temperature of the heat insulating plate 101a measured by the temperature sensor 263 is stored in the memory 121c via the CPU 121a. For example, the data stored in the memory 121c can be visualized as shown in a graph 701 of FIG. 7.

### Determination Step S506

After the temperature sensor 263 measures the surface temperature of the heat insulating plate 101a for a certain period of time, the controller 121 determines whether or not predetermined data is acquired (step S506). When the controller 121 determines, in the determination step S506, that the predetermined data is completely acquired, a subsequent step is performed. When the controller 121 determines, in the determination step S506, that the predetermined data is not completely acquired, the step S504 is performed again.

### Unloading Step S508

When the predetermined data of the heat insulating plate 101a is completely acquired, the boat 217 is unloaded out of the process chamber 201 (step S508).

### Quartz Chip Measurement Preparing and Loading Step S510

After the boat 217 is unloaded, the heat insulating plate 101a is discharged from the boat 217, and as shown in FIG. 6B, the perforated heat insulating plate 602 is held at a position where the heat insulating plate 101a was held. Similarly, after the dummy wafer 601 is discharged, the product wafer or a test wafer (also referred to as the target substrate or the target wafer) 603 made of a material whose thermal characteristics are similar to thermal characteristics of the product wafer is held in the boat 217 at a position where the dummy wafer 601 was held. The quartz chip 604 (which is thin and small) made of a material that does not transmit the detection light of the temperature sensor 263 is installed on a central portion on the wafer 603. When the perforated heat insulating plate 602 and the target wafer 603 on which the quartz chip 604 is installed are held at predetermined positions of the boat 217, the boat 217 is loaded into the process chamber 201 (step S510).

### Temperature Adjusting and Quartz Chip Temperature Measuring Step S512

When the boat 217 is loaded into the predetermined substrate processing position, similar to the step S504 in which the temperature of the heat insulating plate 101a is measured, the microwave is supplied from the microwave oscillator 655 by controlling the microwave oscillator 655 using a control method such as the pulse control 401 and the power limit control 402 described above so as to perform the temperature adjusting operation such as elevating the temperature of the wafer 200 to the substrate processing temperature and maintaining the temperature of the wafer 200. While the temperature adjusting operation is being performed, the measurement of a surface temperature of the quartz chip 604 on the target wafer 603 is started at a predetermined start timing and performed for a predetermined time by the temperature sensor 263 (step S512). The target wafer 603 partially transmits the detection light of the temperature sensor 263, whereas the quartz chip 604 does not transmit the detection light of the temperature sensor 263. Thus, it is possible to accurately measure the temperature of the quartz chip 604.

### Determination Step S514

After the temperature sensor 263 measures the surface temperature of the quartz chip 604 for a certain period of time, the controller 121 determines whether or not predetermined data is acquired (step S514). When the controller 121 determines, in the determination step S514, that the predetermined data is completely acquired, a subsequent step is performed. When the controller 121 determines, in the determination step S514, that the predetermined data is not completely acquired, the step S512 is performed again.

The surface temperature of the quartz chip 604 measured by the temperature sensor 263 is stored in the memory 121c via the CPU 121a. For example, the data stored in the memory 121c can be visualized as shown in a graph 702 of FIG. 7.

### Unloading, Substrate Processing Preparing and Temperature Conversion Graph Generating Step S516

When the predetermined data of the quartz chip 604 is completely acquired, the boat 217 is unloaded out of the process chamber 201. After the boat 217 is unloaded, the perforated heat insulating plate 602 is discharged, and as shown in FIG. 1, the heat insulating plate 101a is held in the boat 217. In addition, the target wafer 603 and the quartz chip 604 are discharged, and the wafer 200 is held in the boat 217. Thereby, preparing for a flow of the substrate processing is performed. From the data of the graph 702 representing a temperature transition (also referred to as a “temperature change”) of the quartz chip 604 with respect to time and the graph 701 representing a temperature transition of the heat insulating plate 101a with respect to time shown in FIG. 7, a correlation between the heat insulating plate 101a and the target wafer 603 is obtained by using a linear interpolation or a linear approximation, and is stored in the memory 121c. For example, as shown in FIG. 8, a vertical axis of the correlation represents the temperature of the quartz chip 604 and a horizontal axis of the correlation represents the temperature of the heat insulating plate 101a. By performing the steps described above, the temperature conversion graph creating step S302 is completed.

### (4) Effects According to Present Embodiments

According to the present embodiments described above, it is possible to provide one or more of the following effects.

(a) By storing the correlation between the heat insulating plate made of a material different from that of the product wafer and the quartz chip on the target wafer whose thermal characteristics are similar to those of the product wafer, it is possible to estimate the temperature of the wafer from the temperature of the heat insulating plate. As a result, it is possible to easily perform the temperature control when the substrate processing is performed.

(b) By estimating the temperature of the wafer from the temperature of the heat insulating plate, it is sufficient to measure the temperature of the heat insulating plate when the wafer is processed. Therefore, it is possible to easily determine the installation location of the temperature sensor.

(c) By measuring the temperature of the heat insulating plate and the temperature of the quartz chip with by the non-contact type thermometer such as the radiation thermometer, it is possible to prevent the thermometer itself from being affected by the microwave. Therefore, it is possible to accurately measure the temperature.

(d) By controlling the microwave oscillator by combining the pulse control and the power limit control when the temperature of the wafer is elevated, it is possible to suppress the temperature difference between the microwave concentrated region and the other regions on the surface of the wafer. It is also possible to suppress the deformation of the wafer such as the cracking, the warping and the distortion. In addition, it is possible to efficiently elevate the temperature of the wafer, and it is also possible to heat the wafer to the desired substrate processing temperature in a short time.

(e) By controlling the microwave oscillator by combining the feedback control and the pulse control when the wafer is heated to the substrate processing temperature, it is possible to maintain the temperature of the wafer at the substrate processing temperature within a predetermined range.

(f) By controlling the pulse width of the pulse control, it is possible to accurately perform the temperature control when the temperature of the wafer is elevated and also when the wafer is processed.

### (5) Modified Examples of Embodiments

While the technique of the present disclosure is described in detail by way of the embodiments described above, the above-described technique is not limited thereto. The above-described technique may be modified in various ways without departing from the gist thereof. For example, the substrate processing apparatus according to the embodiments described above is not limited to the example described above. That is, the substrate processing apparatus may be modified as shown in the following modified examples.

### First Modified Example

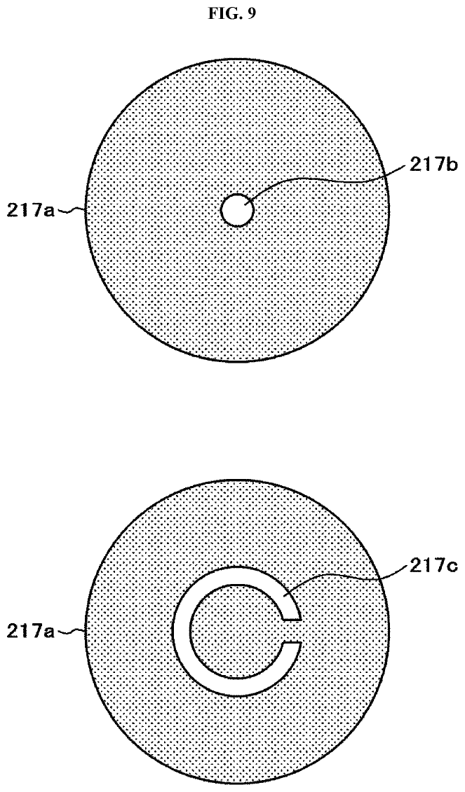

As shown in FIG. 9, according to the first modified example, by shifting an installation position of the non-contact type temperature sensor 263 such as the radiation thermometer outward in a radial direction of the cap flange 104 from a center of the cap flange 104, the hole 217b of the ceiling plate 217a of the boat 217 is replaced with a C-shaped groove 217c. According to the first modified example, as compared with a case where a hole diameter of the hole 217b is increased, it is possible to suppress a decrease in the temperature of the substrate (that is, the wafer) due to the heat dissipated through the ceiling plate 217a of the boat 217.

### Second Modified Example

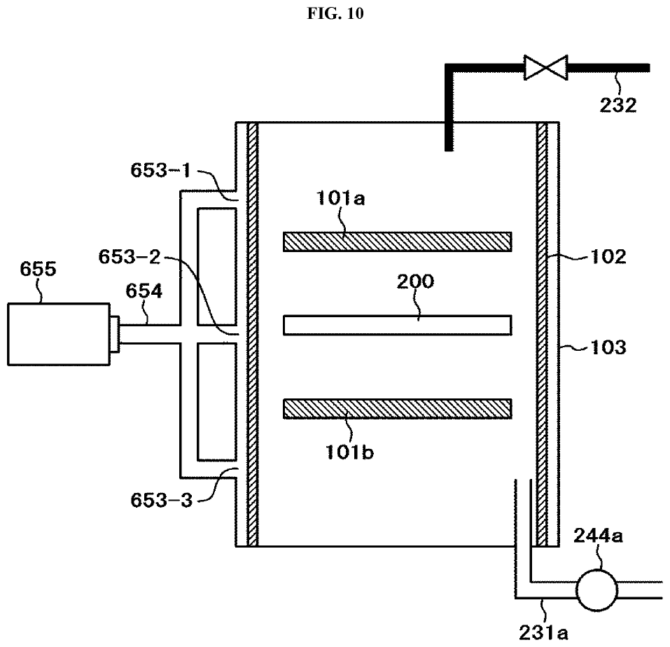

As shown in FIG. 10, according to the second modified example, by branching off a plurality of branches from a single waveguide 654 connected to a single microwave oscillator 655 and connecting the branches of the waveguide 654 to the case 102, a plurality of electromagnetic wave introduction ports 653-1 through 653-3 are provided in the case 102. According to the second modified example, the microwave supplied through each of the plurality of electromagnetic wave introduction ports 653-1 through 653-3 can be uniformly irradiated to the wafer 200. Therefore, it is possible to uniformly heat the wafer 200.

As described above, according to some embodiments in the present disclosure, it is possible to uniformly perform the substrate processing.

What is claimed is:

1. A method of manufacturing a semiconductor device, comprising:
(a) heating a heat insulating plate accommodated in a substrate retainer capable of accommodating a substrate to a processing temperature at which the substrate is processed by an electromagnetic wave supplied from a heater, and measuring a temperature change of the heat insulating plate by a non-contact type thermometer until a temperature of the heat insulating plate reaches the processing temperature;
(b) heating a test object provided with a chip made of a material not transmitting a detection light of the non-contact type thermometer and accommodated in the substrate retainer to the processing temperature by the heater, and measuring a temperature change of the chip by the non-contact type thermometer until a temperature of the chip reaches the processing temperature;
(c) acquiring a correlation between the temperature change of the heat insulating plate and the temperature change of the chip based on measurement results of the temperature change of the heat insulating plate and measurement results of the temperature change of the chip; and
(d) controlling the heater to heat the substrate based on the correlation and the temperature of the heat insulating plate measured by the non-contact type thermometer.

2. The method of claim 1, wherein the chip comprises a quartz chip made of quartz, and a temperature change of the quartz chip is measured in (b).

3. The method of claim 1, wherein a position of the heat insulating plate in (a) is higher than a position of the substrate in (a).

4. The method of claim 1, wherein two or more of heat insulating plates comprising the heat insulating plate are accommodated in the substrate retainer such that the substrate is interposed between the two or more of the heat insulating plates, and the two or more of heat insulating plates are heated by the heater.

5. A substrate processing apparatus comprising:
a process chamber in which a substrate retainer capable of accommodating a substrate and into which a heat insulating plate is loaded;
a heater comprising an electromagnetic wave oscillator configured to generate an electromagnetic wave in the process chamber;
a non-contact type thermometer configured to measure a temperature; and
a controller configured to be capable of performing:
(a) measuring a temperature change of the heat insulating plate by the non-contact type thermometer until a temperature of the heat insulating plate reaches a processing temperature at which the substrate is processed;
(b) measuring a temperature change of a chip provided with a test object accommodated in the substrate retainer and made of a material not transmitting a detection light of the non-contact type thermometer by the non-contact type thermometer until a temperature of the chip reaches the processing temperature;
(c) acquiring a correlation between the temperature change of the heat insulating plate and the temperature change of the chip; and
(d) controlling the heater to heat the substrate based on the correlation and the temperature of the heat insulating plate measured by the non-contact type thermometer.

6. The substrate processing apparatus of claim 5, wherein the chip comprises a quartz chip made of quartz.

7. The substrate processing apparatus of claim 5, wherein a position of the heat insulating plate in (a) is higher than a position of the substrate in (a).

8. The substrate processing apparatus of claim 5, wherein two or more of heat insulating plates comprising the heat insulating plate are accommodated in the substrate retainer such that the substrate is interposed between the two or more of the heat insulating plates.

9. A non-transitory computer-readable recording medium storing a program that causes, by a computer, a substrate processing apparatus to perform:
(a) heating a heat insulating plate accommodated in a substrate retainer capable of accommodating a substrate to a processing temperature at which the substrate is processed by an electromagnetic wave supplied from a heater, and measuring a temperature change of the heat insulating plate by a non-contact type thermometer until a temperature of the heat insulating plate reaches the processing temperature;
(b) heating a test object provided with a chip made of a material not transmitting a detection light of the non-contact type thermometer and accommodated in the substrate retainer to the processing temperature by the heater, and measuring a temperature change of the chip by the non-contact type thermometer until a temperature of the chip reaches the processing temperature;
(c) acquiring a correlation between the temperature change of the heat insulating plate and the temperature change of the chip based on measurement results of the temperature change of the heat insulating plate and measurement results of the temperature change of the chip; and
(d) controlling the heater to heat the substrate based on the correlation and the temperature of the heat insulating plate measured by the non-contact type thermometer.

10. The non-transitory computer-readable recording medium of claim 9, wherein the chip comprises a quartz chip made of quartz, and a temperature change of the quartz chip is measured in (b).

11. The non-transitory computer-readable recording medium of claim 9, wherein a position of the heat insulating plate in (a) is higher than a position of the substrate in (a).

12. The non-transitory computer-readable recording medium of claim 9, wherein two or more of heat insulating plates comprising the heat insulating plate are accommodated in the substrate retainer such that the substrate is interposed between the two or more of heat insulating plates, and the two or more of heat insulating plates are heated by the heater.
